(19) United States
(12) Patent Application Publication
(10) Pub. No.: US 2007/0131992 A1
(43) Pub. Date: Jun. 14, 2007

(54) Multiple photosensor pixel image sensor

(75) Inventors: Taner Dosluoglu, New York, NY (US); Guang Yang, Annandale, NJ (US)

Correspondence Address: GEORGE O. SAILE, 28 DAVIS AVENUE, POUGHKEEPSIE, NY, 12603, US

(73) Assignee: Dialog Semiconductor GmbH

(21) Appl. No.: 11/301,436

(22) Filed: Dec. 13, 2005

(51) Int. Cl. H01L 31/113

(52) U.S. Cl. 257/292

(57) ABSTRACT

A color multiple sensor pixel image sensor includes multiple photo-sensing devices, a combined photosensing and charge storage device, and multiple triggering switches. Each of the multiple photo-sensing devices is structured for conversion of photons of one differentiated color component to photoelectrons. The combined photosensing and charge storage device is structured for conversion of photons of a principal color photoelectrons and connected to sequentially receive photoelectrons from each of the multiple photo-sensing devices. Each triggering switch is connected such that photoelectrons are selectively and sequentially transferred from each of the multiple photo-sensing devices to the combined photosensing and charge storage device. A reset triggering switch is connected with the combined photosensing and charge storage device and those of the triggering switches connected to the combined photosensing and charge storage device to establish reset voltage level after integration and sensing of the photoelectrons.

### RELATED PATENT APPLICATIONS

“Methods and Apparatus for Operation of a Multiple Photosensor Pixel Image Sensor” Attorney's Docket Number DS05-013, Ser. No. ______, Filing Date ______, assigned to the same assignee as this invention and included herein by reference.

“A Multiple Photosensor Pixel” (Dosluoglu—840) Attorney's Docket Number DS05-009, Ser. No. 11/252,840, Filing Date Oct. 18, 2005, assigned to the same assignee as this invention and included herein by reference.

### Background of the Invention

1. Field of the Invention

The present invention relates to solid-state image sensing devices. More particularly, this invention relates to multiple photosensor solid state image sensing devices.

2. Description of Related Art

Integrated circuit image sensors are finding applications in a wide variety of fields, including machine vision, robotics, guidance and navigation, automotive applications, and consumer products such as digital camera and video recorders. Imaging circuits typically include a two dimensional array of photo sensors. Each photo sensor includes one picture element (pixel) of the image. Light energy emitted or reflected from an object impinges upon the array of photo sensors. The light energy is converted by the photo sensors to an electrical signal. Imaging circuitry scans the individual photo sensors to readout the electrical signals. The electrical signals of the image are processed by external circuitry for subsequent display.

Modern metal oxide semiconductor (MOS) design and processing techniques have been developed that provide for the capture of light as charge and the transporting of that charge within active pixel sensors and other structures so as to be accomplished with almost perfect efficiency and accuracy. One class of solid-state image sensors includes an array of active pixel sensors (APS). An APS is a light sensing device with sensing circuitry inside each pixel. Each active pixel sensor includes a sensing element formed in a semiconductor substrate and capable of converting photons of light into electronic signals. As the photons of light strike the surface of a photoactive region of the solid-state image sensors, free charge carriers are generated and collected. Once collected the charge carriers, often referred to as charge packets or photoelectrons are transferred to output circuitry for processing.

An active pixel sensor also includes one or more active transistors within the pixel itself. The active transistors amplify and buffer the signals generated by the light sensing element to convert the photoelectron to an electronic signal prior to transferring the signal to a common conductor that conducts the signals to an output node.

Active pixel sensor devices are fabricated using processes that are consistent with complementary metal oxide semiconductor (CMOS) processes. Using standard CMOS processes allows many signal processing functions and operation controls to be integrated with an array of active pixel sensors on a single integrated circuit chip.

Refer now to FIG. 1a for a detailed discussion of a three transistor photodiode active pixel image sensor of the prior art. A substrate 5 heavily doped with a P-type impurity has its surface further doped with a complementary impurity to create a lightly doped P-type epitaxial layer 10. The N⁺ photo detector region 15 is formed within the surface of the epitaxial layer 10 of the substrate 5. A P-type material is heavily diffused relatively deeply into the surface of the epitaxial layer 10 of the substrate 5 to form the P-well diffusions 20.

The junction of the N⁺ photo detector region 15 with the epitaxial layer 10 is depleted of electrons and acts collection region during the photo conversion. The collected photoelectrons cause the voltage potential N⁺ photo detector region 15 to become more negative in proportion to the number of photons 50 that impinge upon the N⁺ photo detector region 15. The N⁺ photo detector region 15 is connected to the gate of the NMOS transistor 30 that acts as a source follower such that the voltage at the source of the NMOS transistor 30 is proportional to the voltage potential present at the N⁺ photo detector region 15. The drain of the row selection NMOS transistor 35 is connected to the source of the NMOS transistor 30. The source of the row selection transistor NMOS transistor 35 is connected to a pixel output port 55 for further processing. The gate of the row selection transistor NMOS transistor 35 is connected to the row select signal 45 for activation to transfer the sensed signal from the pixel for readout. The NMOS transistor 25 has its drain connected to the power supply voltage source VDD and is source connected to the N⁺ photo detector region 15. The gate of the NMOS transistor is connected to the reset signal 40. When activated the NMOS transistor 25 ties the N⁺ photo detector region 15 to the power supply voltage source VDD to reset the N⁺ photo detector region 15.

In operation the N⁺ photo detector region 15 is initialized by applying the reset signal 40 to the NMOS transistor 25 to reset the N⁺ photo detector region 15. Photons are allowed to impinge upon the N⁺ photo detector region 15 for an integration period. The row select signal 45 is activated and the voltage present at the N⁺ photo detector region 15 is sensed. The reset signal 40 is again applied to reset the N⁺ photo detector region 15 and this reset level is then sensed and the difference determined in a double sampling method of readout.

An alternative to the three transistor photodiode active pixel image sensor is for a detailed discussion of a four transistor pinned photodiode active pixel image sensor of the prior art and shown in FIG. 1b. A substrate 105 heavily doped with a P-type impurity has its surface further doped with a complementary impurity to create a lightly doped P-type epitaxial layer 110. The N⁺ diffusion region 115 of pinned photo detector is formed within the surface of the epitaxial layer 10 of the substrate 5. A shallow P⁺ pinning diffusion 120 is formed within the N⁺ photo detector region 115 to complete the pinned photo detector. A P-type material is heavily diffused relatively deeply into the surface of the epitaxial layer 110 of the substrate 105 to form the P-well diffusions 125 and 130. The shallow P⁺ pinning diffusion 120 is in contact with the P-well 130 which connected to the ground reference voltage. The shallow P⁺ pinning diffusion 120 and the p-type epitaxial layer 110 force the N⁺ photo detector region 115 to be more totally depleted for collecting the photoelectrons resulting from the impingement of the photons 150 on the surface of the pinned photodiode region.

An N⁺ floating diffusion storage node 135 is formed within the P-well diffusion 125 to retain charge that is collected in the N⁺ photo detector region 115. A gate insulator or thin oxide 140 is placed on the surface of the substrate 105 and polycrystalline silicon is formed on the surface to form the transfer gate 145. The N⁺ photo detector region 115, the transfer gate 145, and the floating diffusion 135 form a transfer gate switch.

The transfer gate 145 of the transfer gate switch is connected to a transfer gating signals T_GT 155. The floating diffusion storage node 135 is connected to the gate of the NMOS transistor 160. The drain of the NMOS transistor 160 is connected to the power supply voltage source VDD and the emitter of the NMOS transistor 160 is connected to the drain of the NMOS transistor 165. The gate of the NMOS transistor 165 is connected to the row select signal 170. The NMOS transistor 160 acts as a source follower to buffer the electrical signal created by the photoelectron charge collected in the floating diffusion 135.

The floating diffusion storage node 135 is further connected to the source of the NMOS transistor 180. The drain of the NMOS transistor 180 is connected to the power supply voltage source VDD. The gate of the NMOS transistor 180 is connected to the reset signal 185. The reset signal 185 activates the NMOS transistor 180 to couple the power supply voltage source VDD to the floating diffusion storage node 135 and the N⁺ photo detector region 115

The photons 150 that impinge upon the pinned photodiode formed of the N⁺ photo detector region 115 and the shallow P⁺ pinning diffusion 120 are converted to photoelectrons and collected within the photo detector. At the completion of an integration period for the collection of the photoelectrons, the transfer gate 155 is activated to turn on the transfer gate switch to transfer the collected photoelectrons to the storage node of the floating diffusion 135. When the collected photoelectrons are retained at the floating diffusion 135 the row select signal 170 is activated to turn on the NMOS transistor 165 to gate the pixel output electrical signal PIX_OUT 175 to external circuitry for processing and display. The amplitude of pixel output electrical signal PIX_OUT 175 is indicative of the intensity of the light energy hν or the number of photons 150 absorbed by the pinned photodiode. Once the pixel output electrical signal PIX-OUT 175 is read out the pixel reset signal 185 is activated to turn on the reset gate switch and the N⁺ photo detector region 15 and the floating diffusion storage node 135 are emptied of the photoelectrons.

As is known in the art, a video display is formed of an array of picture elements or pixels. A pixel is one of the smallest complete elemental dots that make up the representation of a picture on a display. Usually the dots are so small and so numerous they appear to merge into a smooth image. The color and intensity of each dot is variable. In color displays the pixels are generally formed of red, green, and blue sub-pixels that are of a size and arrangement that light emitting from them is added to form the color of the whole pixel. Pixels are either rectangular or square.

U.S. Pat. No. 6,903,754 (Brown-Elliott) teaches an arrangement of color pixels for full color imaging devices with simplified addressing referred to as the Pentile Matrix. The architecture of the array consists of an array of rows and column line architecture for a display. The array consists of a plurality of row and column positions and a plurality of three-color pixel elements. A three-color pixel element can comprise a blue emitter, a pair of red emitters, and a pair of green emitters. The blue emitter is placed in the center of a square formed of the pairs of red and green emitters. The pair of red emitters is on opposing corners of the square and the pair of green emitters is adjacent to the red emitters and the other opposing corners of the square.

Image sensor elements (either CMOS or Charged Coupled Devices) generally sense light as a grey-scaled value. Alternately, the pixel sensor elements, as described, are tuned to be sensitive to a particular hue of the color. If the pixel sensor elements sense only grey scale values they require a color filter array to generate the color components that are to be displayed. The color filter arrays, such as the Bayer Pattern as shown in U.S. Pat. No. 3,971,065 (Bayer), provide the color information for an image. Refer to FIG. 2 for a description of a Bayer pattern color array. The first green hue pattern, having elements denoted by G1, assumes every other array position with the red hue pattern of a given row. The second green hue pattern (G2) assumes an every other array position and alternates with the blue hue pattern (B) in alternate rows. In the case of pixel sensor elements detecting the grey scale values, the Bayer pattern color array will be a discrete dyed coating. In the case of those pixel sensor elements capable of sensing the discrete color components, the pixel sensor elements have their sensitivities tuned to receive specific colors and the pixel sensor elements are arranged in the Bayer pattern.

“A CMOS Image Sensor with a Double-Junction Active Pixel”, Findlater, et al., IEEE Transactions on Electron Devices, January 2003, Vol.: 50, Issue: 1, pp.: 3242, describes a CMOS image sensor that employs a vertically integrated double-junction photodiode structure. The imager allows color imaging with only two filters. The sensor uses a 6-transistor pixel array.

U.S. Pat. No. 5,028,970 (Masatoshi) provides an image sensor for sequentially reading signals from photoelectric converting elements disposed in a matrix and formed on a substrate in which both an image sensor and a photometry sensor are incorporated. The sensor includes a light-shielding layer disposed over the area of the substrate except the area of the photoelectric elements, the light-shielding layer forming a lower electrode. A PN-junction photodiode layer is disposed over the light-shielding layer, and an upper transparent electrode layer is disposed at least over the photodiode layer. The upper transparent electrode layer is divided into a plurality of pattern areas. If desired, at least one of the pattern areas of the upper transparent electrode layer may be further divided into a plurality of very small areas and color filters formed over the very small areas.

U.S. Pat. No. 6,111,300 (Cao, et al.) teaches a multiple color detection elevated pin photodiode active pixel sensor formed on a substrate. A diode is electrically connected to a first doped region of the substrate. The diode conducts charge when the diode receives photons having a first range of wavelengths. A second doped region conducts charge when receiving photons having a second range of wavelengths. The photons having the second range of wavelengths pass through the diode substantially undetected by the diode. A doped well within the substrate conducts charge when receiving photons having a third range of wavelengths. The photons having the third range of wavelengths pass through the diode substantially undetected by the diode.

U.S. Pat. No. 6,486,911 (Denyer, et al.) describes an optoelectronic sensor with shuffled readout. The optoelectronic sensor is a multi-spectral image array sensor that senses radiation of different wavelengths e.g. different colors. The array has at least one row of cells containing a plurality of series (R, G) of pixels which series are interspersed with each other. Each series consists essentially of pixels for sensing radiation of substantially the same wavelength e.g. the same color. At least two horizontal shift registers are provided, each register being coupled to pixels of a respective one of the plurality of series (R, G) of pixels so as to enable the outputs from the pixels of each series to be read out consecutively at an array output. The pixels are preferably arranged in a Bayer matrix of Red, Green and Blue pixels and two interleaved shift registers are provided for reading out the pixel outputs for each color consecutively, in each row.

U.S. Pat. No. 6,693,670 (Stark) provides a multi-photodetector unit cell, which includes a plurality of light-detecting unit cells and a single charge-integration and readout circuitry. Typically, each of the cells produces charge representative of the detected light. The integration and readout circuit may be shared by the plurality of unit cells, and used to read-out the charge in real-time. The cluster may also include a switch associated with each unit cell, such that each switch connects its associated unit cell to the circuit. Each unit cell includes a photodetector, a photodiode or a photogate. The circuit includes a shared storage device, a shared reset circuit, or a readout circuit. Typically, the shared storage device may be for accumulating the charge in the focal plane.

U.S. Patent Application 2004/0201073 (Dosluoglu, et al.) provides detecting red and greed light is a single pixel. The pixel includes a deep N well formed in a P type epitaxial substrate. A number of P wells, which are used as the sensor nodes, are formed in the deep N well. The use of these P wells as the sensor nodes improves the modulation transfer function. The depth of the deep N well is about equal to the depth of hole electron pairs generated by red light in silicon. The depth of the P wells is about equal to the depth of hole electron pairs generated by green light in silicon. A red/green signal is determined at each P well by determining the potentials between each of the P wells and the deep N well after a charge integration cycle with the P wells and the deep N well isolated. A green signal is determined at each P well by determining the potentials between each of the P wells and the deep N well after a charge integration cycle with the P wells isolated and the deep N well held at a fixed positive voltage. A red signal at each P well is determined by subtracting the green signal at that P well from the red/green signal at that P well.

U.S. Pat. No. 6,878,918 (Dosluoglu) teaches a circuit and method that suppresses reset noise in active pixel sensor arrays. A circuit having a number of N-wells formed in a P-silicon epitaxial layer or a number of P-wells formed in an N-silicon epitaxial layer is provided. A pixel is formed in each of the wells so that each of the wells is surrounded by silicon of the opposite polarity and an array of pixels is formed. Means are provided for selectively combining or binning adjacent N- or P-wells. During the reset period of the imaging cycle selected groups of adjacent pixels are binned and the charge injected by the resetting of a pixel is averaged among the neighboring pixels, thereby reducing the effect of this charge injection on any one of the pixels and thus reducing the noise generated. The reset is accomplished using a PMOS transistor formed in each N-well or an NMOS transistor formed in each P-well. The selective binning is accomplished using NMOS or PMOS transistors formed in the region between adjacent wells. Conductive traces between adjacent wells can also be used to accomplish the selective binning.

U.S. Pat. No. 5,359,213 (Lee, et al.) describes a charge transfer device capable of transferring signal charge at a high signal to noise ratio (SIN ratio) and preventing an occurrence of dark current. They include a double-layered charge transfer path structure provided by forming a surface channel region on a buried channel region formed in a semiconductor substrate, the surface channel region having a conductivity opposite to that of the buried channel region. The surface channel region of the doubled-layered structure is used for accumulating dark current generated from boundary surfaces between the substrate and a gate insulating film, whereas the buried channel region is used for transferring optical signal charge.

U.S. Pat. No. 5,739,562 (Ackland, et al.) provides an active pixel image sensor that includes an array of pixels arranged in two groups, for instance columns and rows. A first common conductor is coupled to the pixels in the first group for conducting control signals. A second common conductor is coupled to the pixels in the second group for selectively transmitting signals to processing electronics. Each of the pixels includes multiple sensing elements that are each configured for capturing a portion of energy from an object to be imaged. At least one of the sensing elements is of a type distinct from another of the sensing elements, for example, a photogate and a photodiode. An amplifying arrangement is provided for receiving signals from selected sensing elements and for selectively providing output signals to the second common conductor.

U.S. Pat. No. 6,934,050 (Merrill, et al.) provides a method for storing a full Red, Green, Blue (RGB) data set of a three-color image data captured with an imager array formed on a semiconductor substrate. The imager has multiple vertical-color-filter detector groups. Each of the vertical color detector groups is composed of three detector layers each configured to collect photo-generated carriers of a first polarity, separated by intervening reference layers configured to collect and conduct away photo-generated carriers of opposite polarity, the three detector layers being disposed substantially in vertical alignment with respect to one another and having different spectral sensitivities. The three-color image data is then stored as digital data in a digital storage device without performing interpolation on the three-color image data.

### SUMMARY OF THE INVENTION

An object of this invention is to provide a color multiple sensor pixel image sensor fabricated on a surface of a substrate for sensing differentiated color components of light impinging upon the multiple photosensor pixel image sensor.

To accomplish at least this object, a multiple photosensor pixel image sensor includes a plurality of photo-sensing devices, a combined photosensing and charge storage device, and a plurality of triggering switches. The plurality of photosensing devices is formed within the surface of the substrate such that each photo-sensing device is structured for conversion of photons of one of the differentiated color components to photoelectrons. The combined photosensing and charge storage device is formed within the surface of the surface and structured for conversion of photons of a principal color of the differentiated color components to photoelectrons and connected to sequentially receive photoelectrons from each of the plurality of photo-sensing devices. Each triggering switch is connected such that photoelectrons are selectively and sequentially transferred from each of the plurality of photo-sensing devices to the combined photosensing and charge storage device.

The multiple photosensor pixel image sensor further includes at least one reset triggering switch in communication with the combined photosensing and charge storage device and those of the triggering switches connected to the combined photosensing and charge storage device. The reset triggering switch places the plurality of photo-sensing devices and the combined photosensing and charge storage device to a reset voltage level after integration and sensing of the photoelectrons.

The differentiated color components are generally green and blue and the principal color is red. The combined photosensing and charge storage device senses the red principal color with a double sampling readout. The plurality of photo-sensing devices senses the green or blue differentiated color components with a correlated double sampling readout.

At least one of plurality of triggering switches is connected between two of the plurality of photo-sensing devices such that one of the two of the plurality of photo-sensing devices is an intermediary repository of the charge prior to transfer to the combined photosensing and charge storage device. The two of the plurality of photo-sensing devices are connected together provide binning of the charge from the two of the plurality of photo-sensing devices.

Each of the plurality of photo-sensing devices may be pinned photodiodes. The pinned photodiodes are formed of a diffusion of the first conductivity type and a shallow pinning diffusion of the second conductivity type within the diffusion of the first conductivity type and connected to a ground reference level. The diffusion and the shallow pinning diffusion of each of the plurality of photo-sensing devices may be optionally formed in a deep diffusion of the second conductivity type connected to a substrate reference voltage source to deflect stray photoelectrons generated in the substrate beneath a photon sensing area of the multiple photosensor pixel image sensor. The diffusion of the combined photosensing and charge storage device may optionally be formed in a diffusion of the first conductivity type with a sufficient depth to collect photoelectrons converted from photons of the primary color.

The multiple photosensor pixel image further includes at least one readout circuit connected to receive and convert photoelectrons retained by the combined photosensing and charge storage device for conversion to an electronic signal indicative of a magnitude of the color component of the light received by one selected photo-sensing device of the plurality of photo-sensing devices. The readout circuit includes a source follower connected to the storage node to receive and buffer a voltage indicative of a number of photoelectrons retained by the combined photosensing and charge storage device. A pixel select switch is selectively connected to the source follower to transfer the buffered voltage indicative of the number of photoelectrons by the combined photosensing and charge storage device to external circuitry for further processing.

### BRIEF DESCRIPTION OF THE DRAWINGS

FIG. 1a is cross sectional views of a photodiode CMOS active pixel image sensor of the prior art.

FIG. 1b is cross sectional views of a pinned photodiode CMOS active pixel image sensor of the prior art.

FIG. 2 is a diagram illustrating a Bayer patterned color image sensor array of the prior art.

FIGS. 3a-3e are schematic, a top plan view, and cross sectional views of a first embodiment multiple photosensor pixel image sensor of this invention.

FIGS. 4a-4c are cross sectional views of a second embodiment of the multiple photosensor pixel image sensor of this invention.

FIG. 5 is a flowchart illustrating the method for fabricating a multiple photosensor pixel image sensor of this invention.

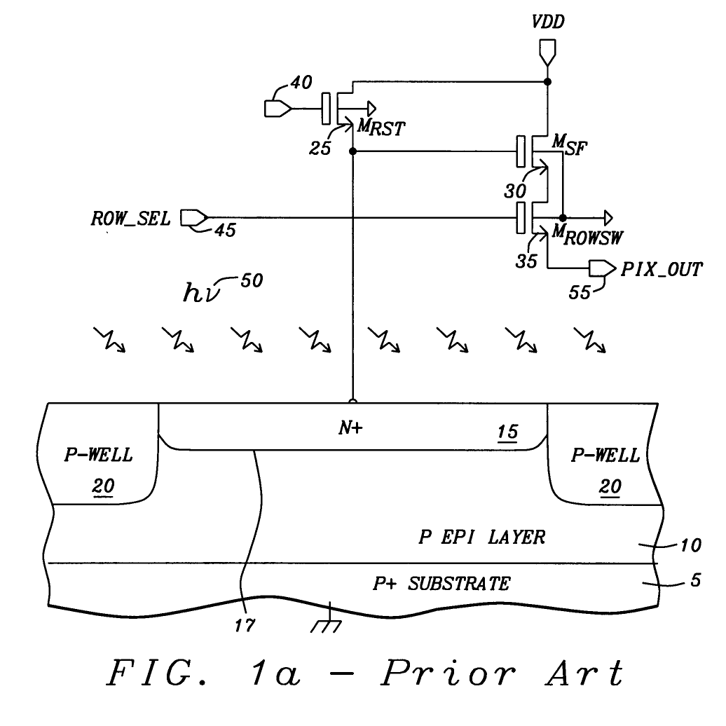

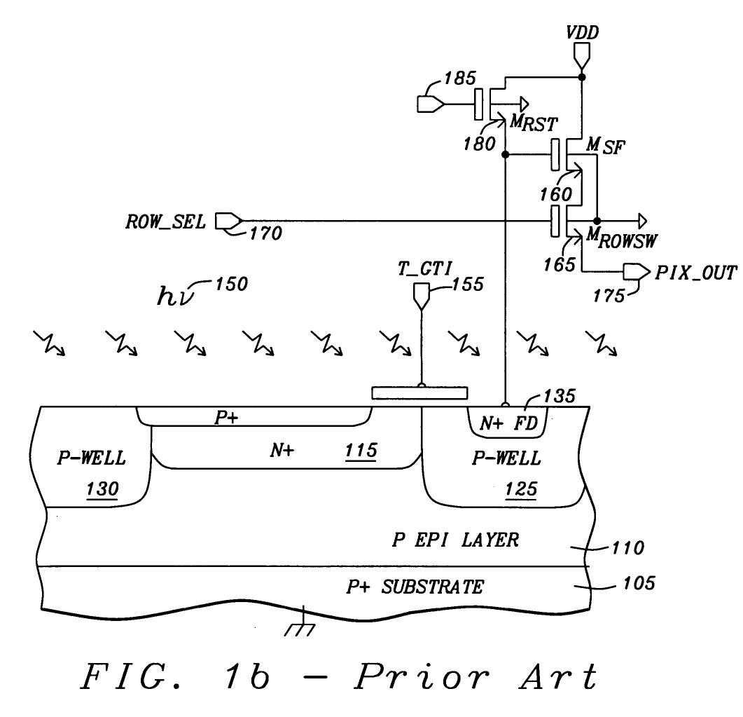

### DETAILED DESCRIPTION OF THE INVENTION

The multiple photosensor pixel image sensor of the preferred embodiment of this invention preferably has four photo-sensing devices formed in a 2×2 matrix. One of the four photo-sensing devices is constructed to act as a combined photosensing and charge storage device and the remaining three devices are standard photodiodes connected to the combined photosensing and charge storage device. In the preferred embodiment, the combined photosensing and charge storage device has its light sensitivity tuned to be sensitive to one principle color component or hue of light emitted or reflected from an object. In the case of a Red, Green, and Blue image sensor, the combined photosensing and charge storage device is tuned to receive a Red hue. Two of the remaining photodiodes are tuned for detecting the same differentiated color component of the light and the third photodiode is tuned for detecting the third of the differentiated color components of the light. In the preferred embodiment the two photodiodes receive the green hue and the third photodiode receives the blue hue.

The two photodiodes that receive the green hue are connected through an NMOS transfer gate to the combined photosensing and charge storage device that receives the red hue. The photodiode that receives the blue hue is connected through an NMOS binning gate to one of the photodiodes that receives the green hue. The combined photosensing and charge storage device is readout with a double sampling process. The combined photosensing and charge storage device is reset and the first photodiode that receives the green hue is readout with correlated double sampling. The combined photosensing and charge storage device is reset and the second photodiode that receives the green hue is readout with correlated double sampling. If the binning gate is connected to the transfer gate of the second photodiode during the readout of second photodiode signal is transferred from photodiode that receives the blue to the first photodiode. The combined photosensing and charge storage device is reset and the first photodiode is readout again using correlated double sampling to detect the blue hue.

The combined photosensing and charge storage device is connected directly to the gate of a source follower NMOS transistor to buffer the voltage level of the combined photosensing and charge storage device that is proportional to the amplitude of the differentiated color components of the light received by the pixel image sensor. A row switching NMOS transistor is connected to the source of the source follower NMOS transistor to gate the output voltage of the source follower transistor to the readout circuitry present at each row of an array of the pixel image sensors.

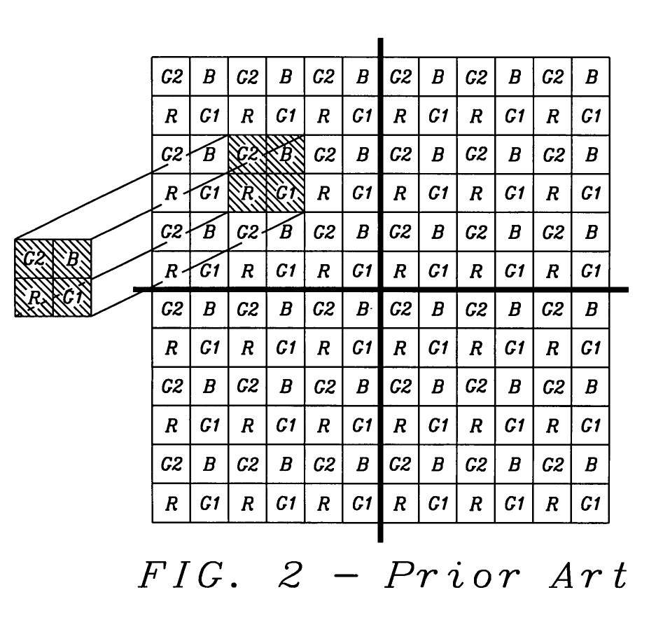

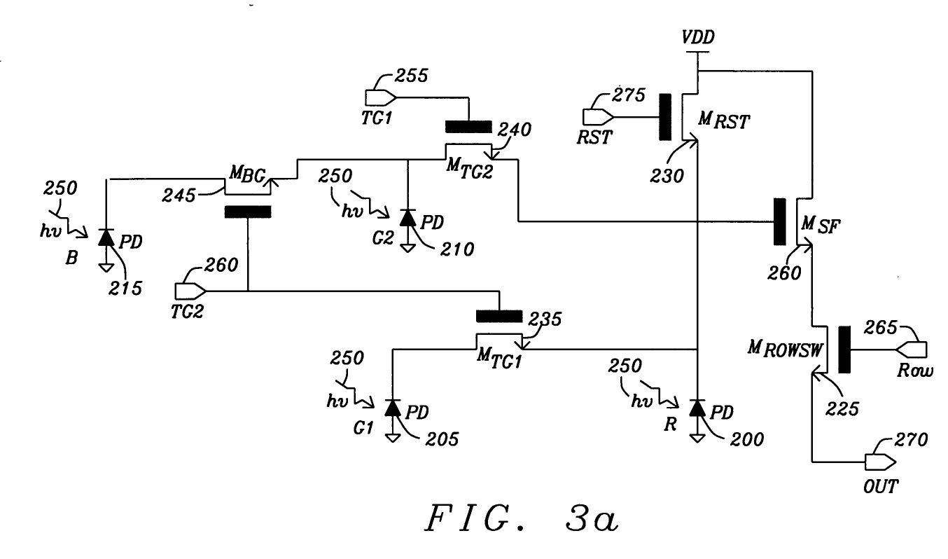

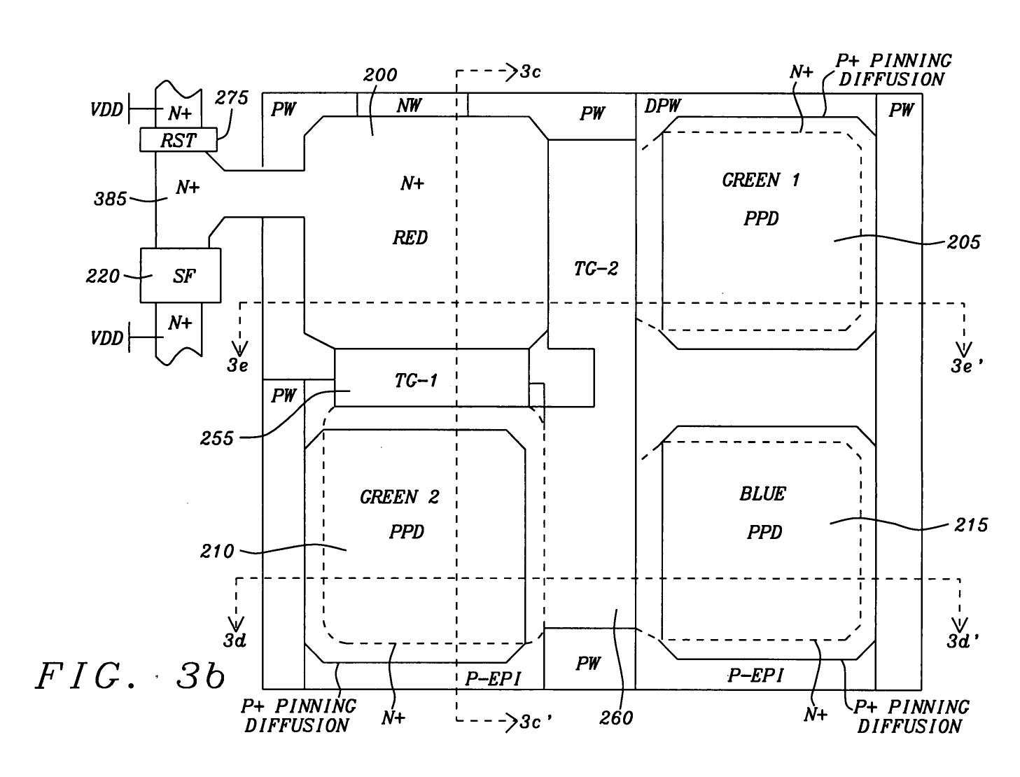

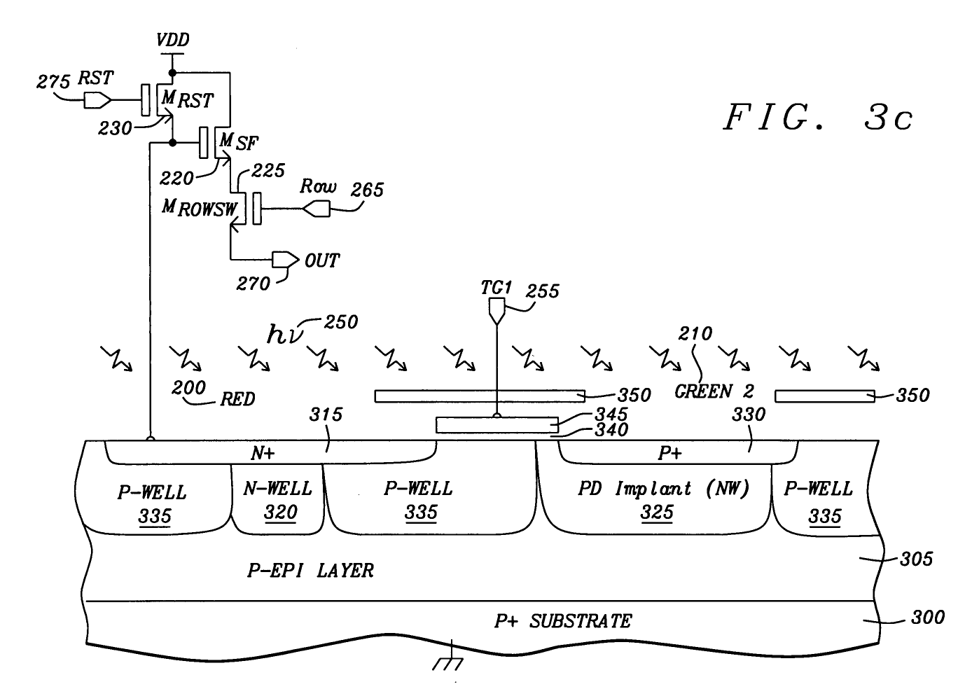

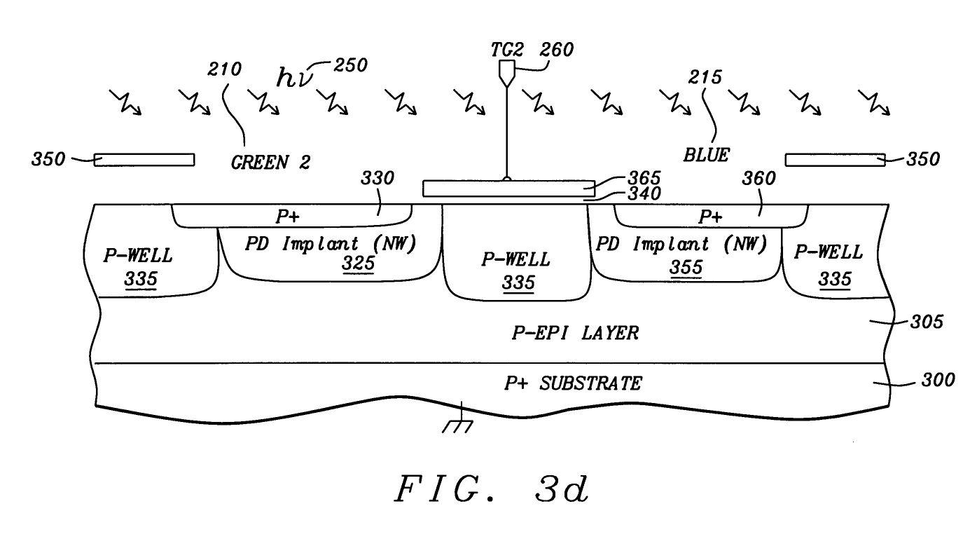

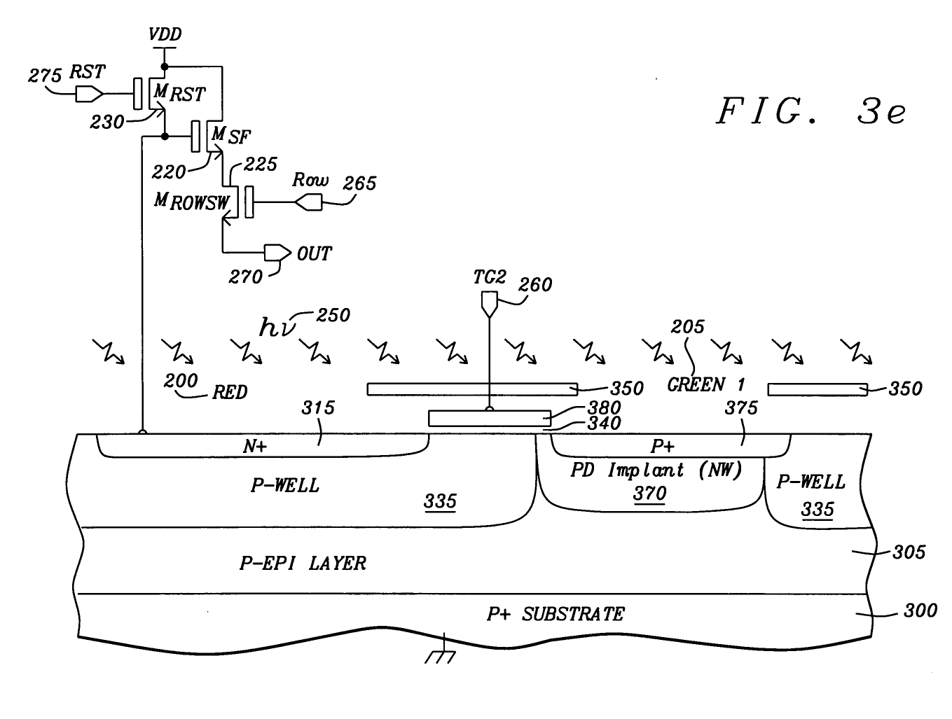

FIG. 3a provides a schematic of the multiple photosensor pixel image sensor of the preferred embodiment of this invention. The pixel image sensor, as shown, has four photodiodes configured in a Bayer pattern color array of FIG. 2. The red photodiode 200 functions as a combined photosensing and charge storage device in that it senses the red differentiated color components of light 250 impinging upon the photodiodes of the pixel image sensor. After the integration and sensing of the red differentiated color components of light 250, the red photodiode 200 is used as the charge storage node for the remaining photosensors of the pixel image sensor.

The first green photodiode 205 is connected through the NMOS transfer gate 235 to the red photodiode 200 and the second green photodiode 210 is connected through the NMOS transfer gate 240 to the red photodiode 200. The blue photodiode 215 is connected through the NMOS binning transfer gate 245 to the first green photodiode 210. The cathode of the red photodiode 200 acts as the photoelectron storage node for the pixel image sensor and is connected to the gate of the source follower NMOS transistor 220. The drain of the source follower NMOS transistor 220 is connected to the power supply voltage source VDD and the source is connected to the drain of the row select NMOS gating transistor 225. The gate of the row select NMOS gating transistor 220 is connected to the row select signal 265 and the source is connected to the output terminal 270 for connection to the readout circuit of a row of an array of the pixel image sensors. The row select signal 265 activates the row select NMOS gating transistor 225 to transfer the voltage at the source of the source follower NMOS transistor 220 to the readout circuitry attached to the row. The voltage at the source of the source follower NMOS transistor 220 is proportional to the number of photons 250 that impinge upon the photodiodes of the pixel image sensor.

The first transfer gate signal 255 is connected to the gate of the NMOS transfer gate 240 and the second transfer gate signal 260 is connected to the gate of the NMOS transfer gate 235 and the gate of the binning transfer gate 245. The first transfer gate signal 255 and the second transfer gate signal 235 provide the control signals for the activation of the NMOS transfer gates 235, 240, and 245 for the transfer of the photoelectrons collected in the conversion of the photons to the red photodiode 200.

The source of the NMOS reset transistor 230 is connected to the cathode of the red photodiode 200 and the sources of the NMOS transfer gates 235 and 240. The drain of the NMOS reset transistor 230 is connected to the power supply voltage source VDD and its gate is connected to the reset signal 275. The pixel image sensor is initiated and each of the photodiodes 200, 205, 210, and 215 are reset by setting the reset signal 275 to turn on the NMOS reset transistor 230. The transfer gate signals 255 and 260 set to activate the NMOS transfer gates 235, 240, and 245. Each of the photodiodes 200, 205, 210, and 215 are then reset.

The NMOS transfer gates 235, 240, and 245 and the NMOS reset transistor 230 are deactivated and the photodiodes 200, 205, 210, and 215 are exposed to the photons of the light 250. The photons are converted within the photodiodes 200, 205, 210, and 215 to generate the photoelectrons. The photodiodes 200, 205, 210, and 215 maybe constructed for receiving similar wavelengths of the light 250 and the colors are filtered using dyed coatings over the photodiodes 200, 205, 210, and 215. Alternately, the photodiodes 200, 205, 210, and 215 have their structure tailored to receive a particular differentiated color component of the light 250. In the preferred embodiment, the combined photosensing and charge storage photodiode 200 is tailored to receive the red hue. The photodiodes 205 and 210 are tailored to receive the green hue and the photodiode 215 is tailored to receive the blue hue.

At the completion of the integration of the photoelectrons at each of the photodiodes 200, 205, 210, and 215, the voltage developed by the red photoelectrons at the cathode of the red photodiode 200 is presented at the gate to of the source follower NMOS transistor 220. The row select signal is set to activate the row select NMOS gating transistor 225 to transfer the voltage present at the source of the source follower NMOS transistor 220 that is proportional to the number of photoelectrons present at the cathode of the red photodiode 200 to the read out circuitry for further processing. The reset signal is then set to activate the NMOS reset transistor 230 to reset the red photodiode 200 and the reset level is then read by the read out circuitry to provide a double sampling reading of the red photodiode 200.

The reset signal 275 is again set to activate the NMOS reset transistor 230 to reset the red photodiode 200 and the reset level is then read by the read out circuitry to provide a reference sampling of the red photodiode 200 for a correlated double sampling of the second green photodiode 210. The first transfer gate signal 255 is set such that the NMOS transfer gate 240 is activated and the charge accumulated during the integration period on the second green photodiode 210 is transferred to the red photodiode 200 acting as the charge storage device of the second green photodiode 210. The charge now present on the red photodiode 200 is applied to the gate of the source follower NMOS transistor 220. The row select signal 265 is set to a level to activate the row select NMOS gating transistor 225 to transfer the voltage present at the source of the source follower NMOS transistor 220 that is proportional to the number of photoelectrons present at the cathode of the red photodiode 200 that were transferred from the second green photodiode 210 to the read out circuitry for further processing.

The first transfer gate signal 255 is set such that the NMOS transfer gate 240 is deactivated and the reset signal 275 is again set to activate the NMOS reset transistor 230 to reset the red photodiode 200 and the reset level is then read by the read out circuitry to provide a reference sampling of the red photodiode 200 for a correlated double sampling of the first green photodiode 205. The second transfer gate signal 260 is set to activate the NMOS transfer gate 235 and the charge accumulated during the integration period on the first green photodiode 205 is transferred to the red photodiode 200 acting as the charge storage device of the first green photodiode 205. The charge now present on the red photodiode 200 is applied to the gate of the source follower NMOS transistor 220. The row select signal 265 is set to a level to activate the row select NMOS gating transistor 225 to transfer the voltage present at the source of the source follower NMOS transistor 220 that is proportional to the number of photoelectrons present at the cathode of the red photodiode 200 that were transferred from the first green photodiode 205 to the read out circuitry for further processing. The second transfer gate signal 260 is set to activate the NMOS binning transfer gate 245 to transfer the charge from the cathode of the blue photodiode 215 to the second green photodiode 210. The second green photodiode 210 acting as a binning device for the blue photodiode 215.

The second transfer gate signal 260 is then set to activate the NMOS transfer gate 235 and the NMOS binning transfer gate 245. The reset signal 275 is again set to activate the NMOS reset transistor 230 to reset the red photodiode 200 and the reset level is then read by the read out circuitry to provide a reference sampling of the red photodiode 200 for a correlated double sampling of the first green photodiode 205 retaining the photoelectron charges from the . The second transfer gate signal 260 is set to activate the NMOS transfer gate 235 and the charge accumulated during the integration period on the first green photodiode 205 is transferred to the red photodiode 200 acting as the charge storage device of the blue photodiode 215 with the first green photodiode 205 acting as the binning device. The charge now present on the red photodiode 200 is applied to the gate of the source follower NMOS transistor 220. The row select signal 265 is set to a level to activate the row select NMOS gating transistor 225 to transfer the voltage present at the source of the source follower NMOS transistor 220 that is proportional to the number of photoelectrons present at the cathode of the red photodiode 200 that were transferred from the blue photodiode 215 to the read out circuitry for further processing. The process is continuously repeated starting with the resetting of the photodiodes 200, 205, 210, and 215 as described above.

Refer now to FIGS. 3b-3e for a discussion of the structure of the multiple photosensor pixel image sensor of this invention. FIG. 3b shows that the photodiodes 200, 205, 210, and 215 are arranged in a 2×2 matrix. The reset signal 275 connected to the NMOS reset transistor to the red photodiode 200 through the N⁺ diffusion 385. Similarly, the source follower 220 is connected through the N⁺ diffusion 385 to the red photodiode 200.

The first transfer gate signal 255 is placed above the NMOS transfer gate 240 between the red photodiode 200 and the second green photodiode 210. The second transfer gate signal 260 placed above the NMOS transfer gate 235 and between the red photodiode 200 and the first green photodiode 205. The second transfer gate signal 260 is further formed above the NMOS binning transfer gate 245 between the second green photodiode 210 and the blue photodiode 215.

The first and second green photodiodes 205 and 210 and the blue photodiode 215 are, in the preferred embodiment, constructed as pinned photodiodes having their diffusion depths tailored for receiving their specific colors. The red photodiode 200 is constructed as a standard photodiode. The first and second green photodiodes 205 and 210 and the blue photodiode 215 are read out using a correlated double sampling process. The red photodiode is read using a double sampling process.

It is known, as shown in “Photodiode Characteristics and Applications”, Product Catalog (2003), UDT Sensors, Inc., Hawthorne, Calif. 90250, found www.udt.com, 915105, that the light is absorbed exponentially with distance from the surface of the substrate and is proportional to the absorption coefficient. The absorption coefficient is very high for shorter wavelengths in the visible blue region (approximately 400 nm) and is small for longer red wavelengths of approximately 1200 nm. Hence, short wavelength photons, such as blue, are absorbed in a thin top surface layer of approximately 100 nm. Silicon becomes transparent to light wavelengths longer than 1200 nm to depths of approximately 100upm. By adjusting the diffusion depths of the photo-sensing devices of the multiple photosensor pixel image sensor of this invention, the sensitivities tuned to be sensitive to one particular color component or hue of light emitted or reflected from an object.

FIG. 3c illustrates the second green and the red photo-sensing devices 210 and 200 of the multiple photosensor pixel image sensor of FIG. 3b. FIG. 3d illustrates the second green and the blue photo-sensing devices 210 and 215 of the multiple photosensor pixel image sensor of FIG. 3b. And FIG. 3e illustrates the red and first green photo-sensing devices 200 and 205 of the multiple photosensor pixel image sensor of FIG. 3b.

Refer now to FIGS. 3c, 3d, and 3e for a discussion structure of multiple photosensor pixel image sensor of this invention. A substrate 300 heavily doped with a P-type impurity has its surface further doped with a complementary impurity to create a lightly doped P-type epitaxial layer 305. A P-type material is diffused into the surface of the substrate 300 to form the contact diffusions not shown for the P-type epitaxial layer 305.

The P-type impurity is diffused into the surface of the substrate 300 to form the P-type wells 335 that define the boundaries for the red, first and second green, and blue photo sensing diodes 200, 205, 210, and 215. The N-type impurity is diffused into the surface of the substrate in the area between the P-type wells 335 to form the N-well 320 that is the junction of the red photodiode 200. This diffusion must be sufficiently deep to insure the conversion of the red photons to photoelectrons and the collection of these photoelectrons. The N-type impurity is also diffused into the surface of the substrate in the area between the P-type wells 335 to form the N-well 325 that is the cathode of the pinned second green photodiodes 210, the N-well 355 that is the cathode of the pinned blue photodiodes 215, and the N-well 370 that is the cathode of the pinned first green photodiodes 205.

The N-type impurity is then diffused on the N-well 320 of the red photodiode to form the N⁺ shallow diffusion 315 that acts as the floating storage node for the pixel image sensor. The P-type impurity is then diffused into the N-well 325, the N-well 355, and N-well 370 to form the pinning diffusions for the pinned first and second green photodiodes 205 and 210 and the blue photodiode 215.

A thin oxide 340 is formed on the surface of the substrate 300 and in the areas of the NMOS transfer gates between red photodiode 200 and the first and second green photodiodes and the NMOS binning transfer gate between the blue photodiode and the second green photodiode. The gate 345 of the NMOS transfer gate between the red photodiode 200 and the second green photodiode 210, the gate 365 of the NMOS binning transfer gate between the second green photodiode 210 and the blue photodiode 205, the gate of the NMOS transfer gate between the red photodiode 200 and the first green photodiode 205 are formed on the surface of the thin oxide. The gate 345 of NMOS transfer gate is connected to the first transfer gate signal 255. The gate 365 of the binning transfer gate and the gate 380 are connected to the second transfer gate signal 260.

The shallow N⁺ well 315 of the red photodiode 200 acts as the photoelectron storage node for the pixel image sensor and is connected to the gate of the source follower NMOS transistor 220. The drain of the source follower NMOS transistor 220 is connected to the power supply voltage source VDD and the source is connected to the drain of the row select NMOS gating transistor 225. The gate of the row select NMOS gating transistor 220 is connected to the row select signal 265 and the source is connected to the output terminal 270 for connection to the readout circuit of a row of an array of the pixel image sensors. The row select signal 265 activates the row select NMOS gating transistor 225 to transfer the voltage at the source of the source follower NMOS transistor 220 to the readout circuitry attached to the row. The voltage at the source of the source follower NMOS transistor 220 is proportional to the number of photons 250 that impinge upon the photodiodes of the pixel image sensor.

An optional metal shield 350 may be placed over the transfer gate switches and the reset gate switches to prevent the light energy 250 from impinging upon the NMOS transfer gates, the NMOS binning transfer gate, and the reset gate switch and is not converted to stray photoelectrons that collect. The metal shield 350 maybe either a separate shield placed above the transfer gate switches and the reset gate switches or maybe the interconnecting wiring, interlayer vias, and substrate contact metallurgy placed above the transfer gate switches, and the reset gate switches.

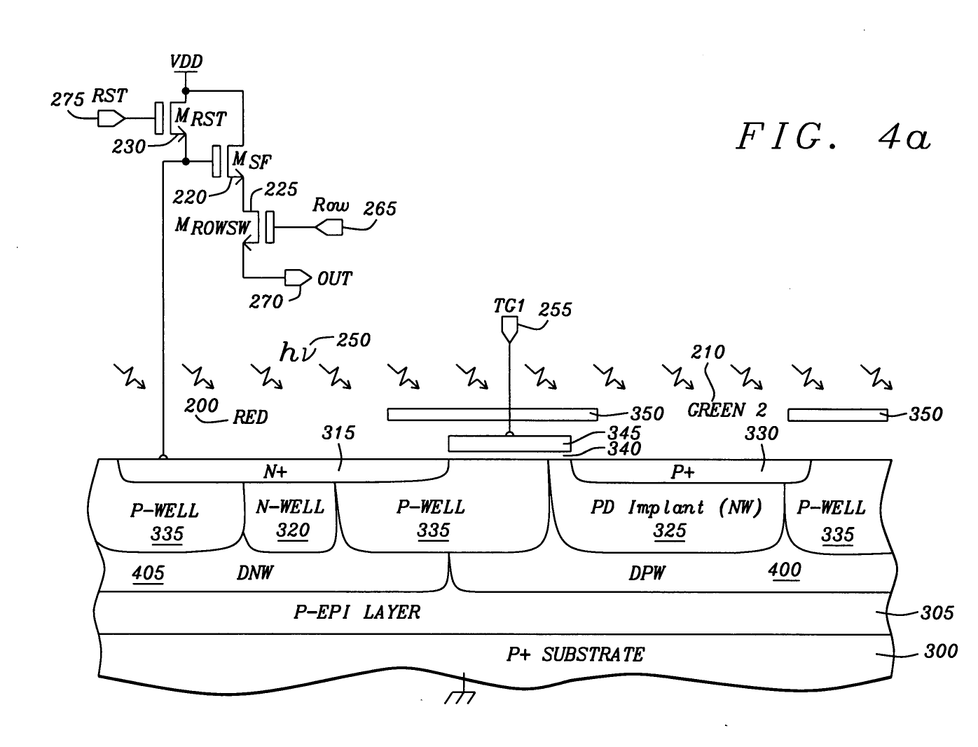

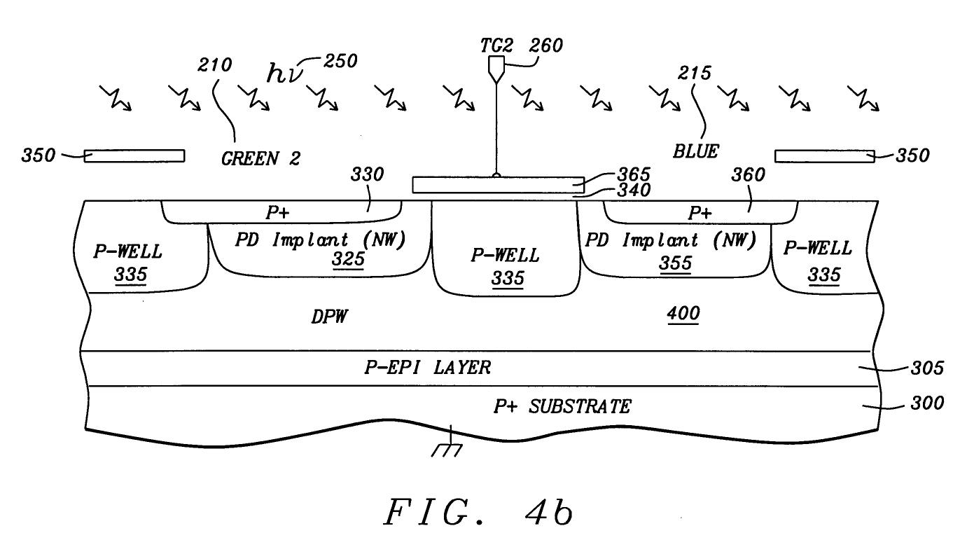

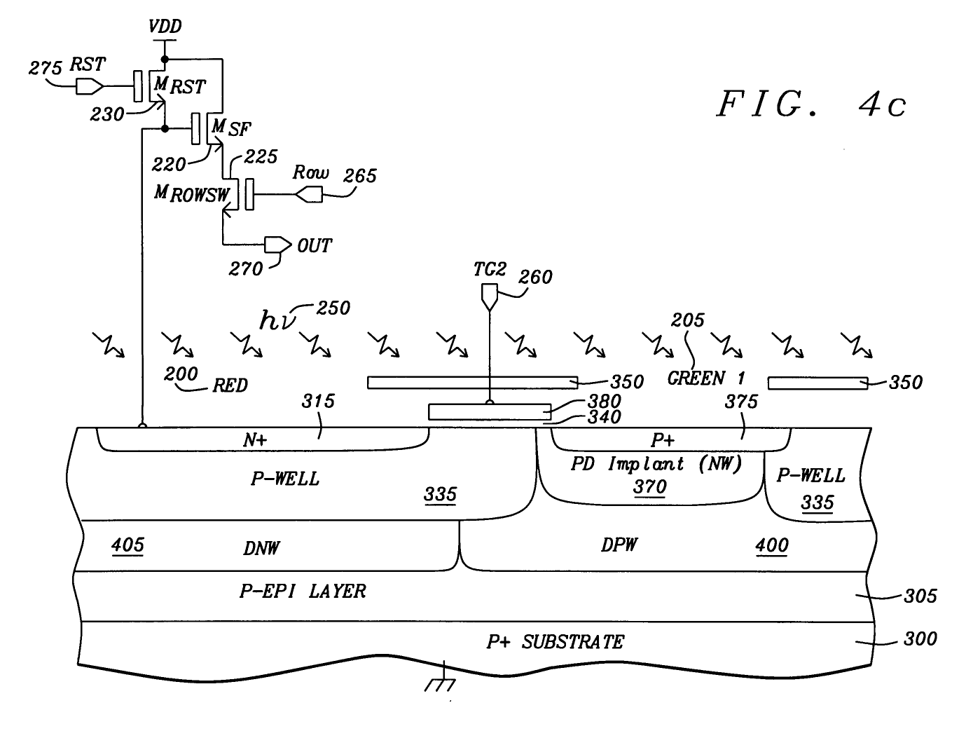

Refer now to FIGS. 4a-4c for a second embodiment of the multiple photosensor pixel image sensor of this invention is also preferably structured in a four photo-sensing devices formed in a 2×2 matrix. The basic structure of the second embodiment is identical to that of the first embodiment as shown in FIGS. 3b-3e but with the addition of the deep P-well diffusion 400 and the deep N-well diffusion 405. The P-type impurity is diffused into the surface of the substrate to a great depth to form the deep P-well diffusion 400. The first and second green photodiodes 205 and 210 are formed in the deep P-well diffusion in a manner as described above. Similarly, the blue photodiode 215 is formed in the deep P-well diffusion 400 as described above. The deep P-well diffusion 400 is connected to the ground reference voltage source to isolate the N-well 325 that is the cathode of the pinned second green photodiodes 210, the N-well 355 that is the cathode of the pinned blue photodiodes 215, and the N-well 370 that is the cathode of the pinned first green photodiodes 205.

The N-type impurity is diffused in the surface of the substrate to a great depth to the deep N-well diffusion 405. The red photodiode 200 is then formed as described above in the deep N-well diffusion 405. The deep N-well diffusion 405 is connected to the power supply voltage source VDD to collect the photoelectrons generated by the photon of the light in the red hue of the spectrum.

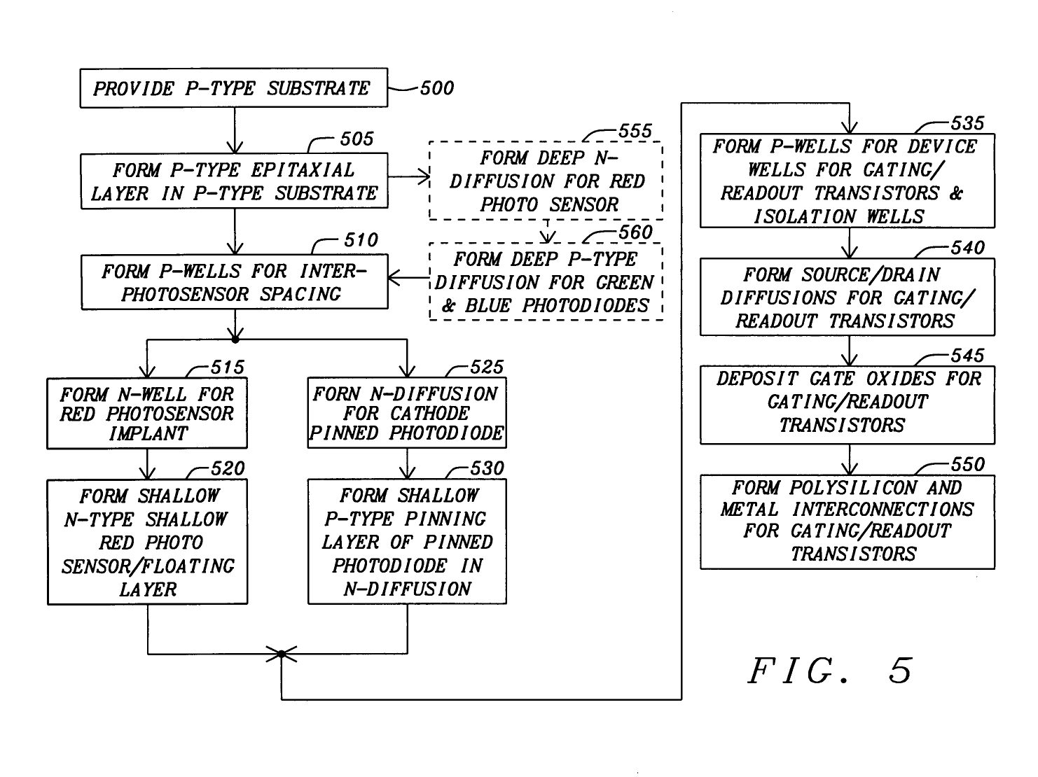

Refer now to FIG. 5 for a method for fabricating an integrated circuit having an array of multiple photosensor pixel image sensors on a provided P-type substrate (Box 500). The substrate has a complementary impurity diffused into its surface (Box 505) to create a lightly doped P-type epitaxial layer. A P-type impurity is diffused into the surface of the substrate to form (Box 510) the inter-photosensor spacings for the multiple photosensor pixel image sensor. An N-type impurity is diffused into the surface of the substrate between certain of the P-wells to form (Box 515) the N-well for the red photosensor implant. The N-type impurity is diffused into the surface of the substrate between others of the P-wells to form (Box 525) N-wells for the cathode of the pinned photodiodes of the first and second green photodiodes and the blue photodiode. The N-type impurity is diffused to a shallow depth into the surface of the substrate above certain of the P-wells and in contact with the N-well of the red photosensor to form (Box 520) the shallow floating layer of the red photosensor. The p-type impurity is diffused to a shallow depth into the surface of the substrate in contact with certain of the P-wells and above N-wells of the cathodes of the pinned photodiodes of the first and second green photodiodes and the blue photodiode to form (Box 530) the pinning layer of the pinned photodiodes of the first and second green photodiodes and the blue photodiode.

The P-type impurity is diffused into the substrate to form (Box 535) the P-wells into which the transfer and binning gating and the readout devices are to be formed. The source/drain diffusions of the transfer gating and readout transistors are formed (Box 540). A gate oxide is formed (Box 545) on the surface of the substrate for the transfer gating and readout transistors. The appropriate polysilicon gates and metal interconnections are formed (Box 550) to complete the transfer gating and readout transistors and their interconnections within the array as described above in FIG. 2b-2e.

For the second embodiment of the multiple photosensor pixel image sensor of this invention, upon the diffusion (Box 505) of the complementary impurity to create the epitaxial layer, the N-type impurity is diffused into the surface of the substrate to a great depth to form (Box 555) the deep N-well diffusion. The deep N-well diffusion is connected to the power supply voltage source VDD and acts to collect the stray photo electrons to prevent excess noise in the red photodiode. The P-type impurity is diffused into the surface of the substrate to a great depth to form (Box 560) the deep P-well diffusion. The deep P-well diffusion acts to isolate the first and second green photodiodes and the blue photodiode to insure that the photoelectrons are collected and do not escape to become noise for other photodiodes.

The Pentile Matrix—Multiple Photosensor Pixel as described in Dosluoglu—840 may be implemented in as a group of 2×2 photo sensor elements. The structure of the Pentile Matrix of Dosluoglu—840 may have photo sensors that are tuned to receive other wavelengths of light such as Red/Green and Green/Blue. The multiple photosensor pixel image sensor of this invention may use colors other than RED as the pixel of the storage node. The use of RED pixel as the storage node is not fundamental to this invention. Any of the photodiodes that are part of the 2×2 element can be used as the storage node regardless of the type of photodiode used and regardless of the type of color filter used above these diodes. A pixel array that is optimized for Pentile Matrix display where the 2×2 structures can be formed using the Green/Blue photodiode that is sensitive to Green and Blue wavelengths only and not Red wavelengths; and the Red/Green photodiode that is sensitive to Red and Green wavelengths and not to Blue wavelengths. It should be noted that in this case the Blue/Green type photodiode has a shallow junction.

It is in keeping with this invention to have a 2×2 multiple photosensor pixel image sensor consisting of one Blue/Green photodiode and three Red/Green photodiodes. The Blue/Green photodiode is used as the storage node. The Red/Green photodiodes may be pinned photodiode structures with deeper than typical pinning implant to reduce its blue response. These Red/Green photodiodes would be connected through the transfer gates to transfer charges the Blue/Green diode in a manner analogous to the Red photodiode of the preferred embodiment of the multiple photosensor pixel image sensor of this invention as shown schematically in FIG. 3a and explained above. While this invention has been particularly shown and described with reference to the preferred embodiments thereof, it will be understood by those skilled in the art that various changes in form and details, such as the above described Pentile Matrix, may be made without departing from the spirit and scope of the invention.

The invention claimed is:

1. A color multiple sensor pixel image sensor fabricated on a surface of a substrate for sensing differentiated color components of light impinging upon said multiple photosensor pixel image sensor, said multiple photosensor pixel image sensor comprising:
a plurality of photo-sensing devices formed within said surface of said substrate, each photo-sensing device is structured for conversion of photons of one of said differentiated color components to photoelectrons;
a combined photosensing and charge storage device formed within said surface of said surface and structured for conversion of photons of a principal color of said differentiated color components to photoelectrons and connected to sequentially receive photoelectrons from each of said plurality of photo-sensing devices; and
a plurality of triggering switches, each triggering switch connected such that photoelectrons are selectively and sequentially transferred from each of the plurality of photo-sensing devices to said combined photosensing and charge storage device.

2. The multiple photosensor pixel image sensor of claim 1 further comprising:
at least one reset triggering switch in communication with said combined photosensing and charge storage device and those of said triggering switches connected to said combined photosensing and charge storage device to place said plurality of photo-sensing devices said combined photosensing and charge storage device to a reset voltage level after integration and sensing of said photoelectrons.

3. The multiple photosensor pixel image sensor of claim 1 wherein said differentiated color components are selected from the group of color components consisting of green and blue.

4. The multiple photosensor pixel image sensor of claim 1 wherein said combined photosensing and charge storage device said principal color is red.

5. The multiple photosensor pixel image sensor of claim 1 wherein said combined photosensing and charge storage device is sensed with a double sampling readout.

6. The multiple photosensor pixel image sensor of claim 1 wherein said plurality of photo-sensing devices are sensed with a correlated double sampling readout.

7. The multiple photosensor pixel image sensor of claim 1 wherein at least one of plurality of triggering switches are connected between two of said plurality of photo-sensing devices such that one of said two of said plurality of photo-sensing devices is an intermediary repository of said charge prior to transfer to said combined photosensing and charge storage device.

8. The multiple photosensor pixel image sensor of claim 7 wherein said two of said plurality of photo-sensing devices are connected together to provide binning of said charge from said two of the plurality of photo-sensing devices.

9. The multiple photosensor pixel image sensor of claim 1 wherein each of said plurality of photo-sensing devices are pinned photodiodes.

10. The multiple photosensor pixel image sensor of claim 9 wherein said pinned photodiodes comprise a diffusion of the first conductivity type and a shallow pinning diffusion of the second conductivity type within said diffusion of the first conductivity type and connected to a ground reference level.

11. The multiple photosensor pixel image sensor of claim 10 wherein each of said plurality of photo-sensing devices further comprises a deep diffusion of said second conductivity type connected to a substrate reference voltage source to deflect stray photoelectrons generated in said substrate beneath a photon sensing area of said multiple photosensor pixel image sensor.

12. The multiple photosensor pixel image sensor of claim 1 wherein said combined photosensing and charge storage device comprises a diffusion of said first conductivity type with a sufficient depth to collect photoelectrons converted from photons of said primary color.

13. The multiple photosensor pixel image sensor of claim 12 further comprises a deep diffusion of said first conductivity type into which said combined photosensing and charge storage device is formed and connected to a power supply voltage source to collect stray photoelectrons generated in said substrate beneath a photon sensing area of said multiple photosensor pixel image sensor.

14. The multiple photosensor pixel image sensor of claim 1 further comprising at least one readout circuit connected to receive and convert photoelectrons retained by said combined photosensing and charge storage device for conversion to an electronic signal indicative of a magnitude of said color component of said light received by one selected photo-sensing device of said plurality of photo-sensing devices.

15. The multiple photosensor pixel image sensor of claim 13 wherein said readout circuit further comprises:
a source follower connected to said storage node to receive and buffer a voltage indicative of a number of photoelectrons retained by said combined photosensing and charge storage device; and
a pixel select switch selectively connected to said source follower to transfer said buffered voltage indicative of the number of photoelectrons by said combined photosensing and charge storage device to external circuitry for further processing.

16. A multiple photosensor pixel image sensor fabricated on a surface of a substrate for sensing differentiated color components of light impinging upon said multiple photosensor pixel image sensor, said multiple photosensor pixel image sensor comprising:
three photo-sensing devices each of said three photo-sensing device is structured for conversion of photons of one of said differentiated color components to photoelectrons and
one combined photosensing and charge storage device formed within said surface of said surface and structured for conversion of photons of a principal color of said differentiated color components to photoelectrons and connected to sequentially receive photoelectrons from each of said plurality of photo-sensing devices; and
a plurality of triggering switches, each triggering switch connected such that photoelectrons are selectively and sequentially transferred from each of the three photo-sensing devices to said combined photosensing and charge storage device;

17. The multiple photosensor pixel image sensor of claim 16 wherein said three photo-sensing devices and one combined photosensing and charge storage device are arranged in a two photosensor by two photo sensor pattern.

18. The multiple photosensor pixel image sensor of claim 16 wherein a first of said plurality of triggering switches connects a first of said three photo-sensing devices to the one combined photosensing and charge storage device.

19. The multiple photosensor pixel image sensor of claim 18 wherein a second of said plurality of triggering switches connects a second of said three photo-sensing devices to a third of said three photo-sensing devices, and a third of said plurality of triggering switches connects said third of said three photo-sensing devices to said one combined photosensing and charge storage device.

20. The multiple photosensor pixel image sensor of claim 19 wherein two of said three photo-sensing devices sense a green color component of light, one of said three photo-sensing devices senses a blue color component of light, and the one combined photosensing and charge storage device senses a red color component and said two photosensor by two photo sensor pattern is a Bayer pattern.

21. The multiple photosensor pixel image sensor of claim 19 wherein photoelectrons present on said one combined photosensing and charge storage device is sensed as a double sampling readout.

22. The multiple photosensor pixel image sensor of claim 19 wherein photoelectrons present on the first of said three photo-sensing devices are sensed as a correlated double sampling with said one combined photosensing and charge storage device acting as a floating storage diffusions for receiving said photoelectrons through said first of said plurality of triggering switches during said correlated double sampling.

23. The multiple photosensor pixel image sensor of claim 19 wherein photoelectrons present on the second of said three photo-sensing devices are sensed as a correlated double sampling with said one combined photosensing and charge storage device acting as a floating storage diffusions for receiving said photoelectrons through said second of said plurality of triggering switches during said correlated double sampling.

24. The multiple photosensor pixel image sensor of claim 23 wherein photoelectrons present on the third of said three photo-sensing devices are sensed as a correlated double sampling with said one combined photosensing and charge storage device acting as a floating storage diffusions for receiving said photoelectrons through said first and third of said plurality of triggering switches during said correlated double sampling.

25. The multiple photosensor pixel image sensor of claim 16 wherein each of said three photo-sensing devices are pinned photo diodes.

26. The multiple photosensor pixel image sensor of claim 25 wherein said pinned photodiodes comprise a diffusion of the first conductivity type and a shallow pinning diffusion of the second conductivity type within said diffusion of the first conductivity type and connected to a ground reference level.

27. The multiple photosensor pixel image sensor of claim 25 further comprising a deep diffusion of said second conductivity type into which said pinned photo diodes are formed and connected to a substrate reference voltage source to deflect stray photoelectrons generated in said substrate beneath a photon sensing area of said multiple photosensor pixel image sensor.

28. The multiple photosensor pixel image sensor of claim 16 further comprising a deep diffusion of said first conductivity type into which said one combined photosensing and charge storage device is formed and connected to a power supply voltage source to collect stray photoelectrons generated in said substrate beneath a photon sensing area of said multiple photosensor pixel image sensor.

29. The multiple photosensor pixel image sensor of claim 16 further comprising at least one readout circuit connected to receive and convert photoelectrons retained by one combined photosensing and charge storage device for conversion to an electronic signal indicative of a magnitude of said color component of said light received by one selected photo-sensing device.

30. The multiple photosensor pixel image sensor of claim 29 wherein said readout circuit further comprises:
a source follower connected to said one combined photosensing and charge storage device to receive and buffer a voltage indicative of a number of photoelectrons retained by said one combined photosensing and charge storage device; and
a pixel select switch selectively connected to said source follower to transfer said buffered voltage indicative of the number of photoelectrons by said one combined photosensing and charge storage device to external circuitry for further processing.

31. A pixel image sensor integrated circuit fabricated on a substrate comprising:
an array of multiple photosensor pixel image sensors for sensing differentiated color components of light impinging upon said multiple photosensor pixel image sensors, each of said multiple photosensor pixel image sensors comprising:
a plurality of photo-sensing devices formed within said surface of said substrate, each photo-sensing device is structured for conversion of photons of one of said differentiated color components to photoelectrons;
a combined photosensing and charge storage device formed within said surface of said surface and structured for conversion of photons of a principal color of said differentiated color components to photoelectrons and connected to sequentially receive photoelectrons from each of said plurality of photo-sensing devices; and
a plurality of triggering switches, each triggering switch connected such that photoelectrons are selectively and sequentially transferred from each of the plurality of photo-sensing devices to said combined photosensing and charge storage device.

32. The pixel image sensor integrated circuit of claim 31 wherein each multiple photosensor pixel image sensor further comprises:
at least one reset triggering switch in communication with said combined photosensing and charge storage device and those of said triggering switches connected to said combined photosensing and charge storage device to place said plurality of photo-sensing devices said combined photosensing and charge storage device to a reset voltage level after integration and sensing of said photoelectrons.

33. The pixel image sensor integrated circuit of claim 31 wherein said differentiated color components are selected from the group of color components consisting of green and blue.

34. The pixel image sensor integrated circuit of claim 31 wherein said combined photosensing and charge storage device said principal color is red.

35. The pixel image sensor integrated circuit of claim 31 wherein said combined photosensing and charge storage device is sensed with a double sampling readout.

36. The pixel image sensor integrated circuit of claim 31 wherein said plurality of photo-sensing devices is sensed with a correlated double sampling readout.

37. The pixel image sensor integrated circuit of claim 31 wherein at least one of plurality of triggering switches are connected between two of said plurality of photo-sensing devices such that one of said two of said plurality of photo-sensing devices is an intermediary repository of said charge prior to transfer to said combined photosensing and charge storage device.

38. The pixel image sensor integrated circuit of claim 37 wherein said two of said plurality of photo-sensing devices is connected together to provide binning of said charge from said two of the plurality of photo-sensing devices.

39. The pixel image sensor integrated circuit of claim 31 wherein each of said plurality of photo-sensing devices is pinned photodiodes.

40. The pixel image sensor integrated circuit of claim 39 wherein said pinned photodiodes comprise a diffusion of the first conductivity type and a shallow pinning diffusion of the second conductivity type within said diffusion of the first conductivity type and connected to a ground reference level.

41. The pixel image sensor integrated circuit of claim 40 wherein each of said plurality of photo-sensing devices further comprises a deep diffusion of said second conductivity type connected to a substrate reference voltage source to deflect stray photoelectrons generated in said substrate beneath a photon sensing area of said multiple photosensor pixel image sensor.

42. The pixel image sensor integrated circuit of claim 31 wherein said combined photosensing and charge storage device comprises a diffusion of said first conductivity type with a sufficient depth to collect photoelectrons converted from photons of said primary color.

43. The pixel image sensor integrated circuit of claim 42 further comprises a deep diffusion of said first conductivity type into which said combined photosensing and charge storage device is formed and connected to a power supply voltage source to collect stray photoelectrons generated in said substrate beneath a photon sensing area of said multiple photosensor pixel image sensor.

44. The pixel image sensor integrated circuit of claim 31 wherein said multiple photosensor pixel image sensor further comprises at least one readout circuit connected to receive and convert photoelectrons retained by said combined photosensing and charge storage device for conversion to an electronic signal indicative of a magnitude of said color component of said light received by one selected photo-sensing device of said plurality of photo-sensing devices.

45. The pixel image sensor integrated circuit of claim 44 wherein said readout circuit further comprises:
a source follower connected to said storage node to receive and buffer a voltage indicative of a number of photoelectrons retained by said combined photosensing and charge storage device; and
a pixel select switch selectively connected to said source follower to transfer said buffered voltage indicative of the number of photoelectrons by said combined photosensing and charge storage device to external circuitry for further processing.

46. A method for fabricating a pixel image sensor integrated circuit on a substrate comprising the steps of:
forming an array of multiple photosensor pixel image sensors for sensing differentiated color components of light impinging upon said multiple photosensor pixel image sensors, wherein forming each of said multiple photosensor pixel image sensors comprises the steps of:
forming a plurality of photo-sensing devices within said surface of said substrate by the step of structuring each photo-sensing device for conversion of photons of one of said differentiated color components to photoelectrons,
forming a combined photosensing and charge storage device within said surface of said surface by the steps of:
structuring said combined photosensing and charge storage device for conversion of photons of a principal color of said differentiated color components to photoelectrons, and
connecting said combined photosensing and charge storage device to sequentially receive photoelectrons from each of said plurality of photo-sensing devices;
forming a plurality of triggering switches; and
connecting each triggering switch such that photoelectrons are selectively and sequentially transferred from each of the plurality of photo-sensing devices to said combined photosensing and charge storage device.

47. The method for fabricating said pixel image sensor integrated circuit of claim 46 wherein forming each multiple photosensor pixel image sensor further comprises the step of:
forming at least one reset triggering switch in communication with said combined photosensing and charge storage device and those of said triggering switches connected to said combined photosensing and charge storage device to place said plurality of photo-sensing devices said combined photosensing and charge storage device to a reset voltage level after integration and sensing of said photoelectrons.

48. The method for fabricating said pixel image sensor integrated circuit of claim 46 wherein said differentiated color components are selected from the group of color components consisting of green and blue.

49. The method for fabricating said pixel image sensor integrated circuit of claim 46 wherein said combined photosensing and charge storage device said principal color is red.

50. The method for fabricating said pixel image sensor integrated circuit of claim 46 wherein said combined photosensing and charge storage device is sensed with a double sampling readout.

51. The method for fabricating said pixel image sensor integrated circuit of claim 46 wherein said plurality of photo-sensing devices is sensed with a correlated double sampling readout.

52. The method for fabricating said pixel image sensor integrated circuit of claim 46 further comprising the step of connecting at least one of said plurality of triggering switches between two of said plurality of photo-sensing devices such that one of said two of said plurality of photo-sensing devices is an intermediary repository of said charge prior to transfer to said combined photosensing and charge storage device.

53. The method for fabricating said pixel image sensor integrated circuit of claim 52 further comprises the step of connecting said two of said plurality of photo-sensing devices together to provide binning of said charge from said two of the plurality of photo-sensing devices.

54. The method for fabricating said pixel image sensor integrated circuit of claim 46 wherein each of said plurality of photo-sensing devices is pinned photodiodes.

55. The method for fabricating said pixel image sensor integrated circuit of claim 54 wherein forming each of said plurality of photo-sensing devices further comprises the step of forming said pinned photodiodes by the steps of:
forming a diffusion of the first conductivity type;
forming a shallow pinning diffusion of the second conductivity type within said diffusion of the first conductivity type; and
connecting said shallow pinning diffusion of the second conductivity type to a ground reference level.

56. The method for fabricating said pixel image sensor integrated circuit of claim 55 wherein forming each of said plurality of photo-sensing devices further comprises the step of forming a deep diffusion of said second conductivity type connected to a substrate reference voltage source to deflect stray photoelectrons generated in said substrate beneath a photon sensing area of said multiple photosensor pixel image sensor.

57. The method for fabricating said pixel image sensor integrated circuit of claim 46 wherein forming said combined photosensing and charge storage device comprises the step of forming a diffusion of said first conductivity type with a sufficient depth to collect photoelectrons converted from photons of said primary color.

58. The method for fabricating said pixel image sensor integrated circuit of claim 57 further comprises the steps of:
forming a deep diffusion of said first conductivity type into which said combined photosensing and charge storage device is formed; and
connecting said deep diffusion to a power supply voltage source to collect stray photoelectrons generated in said substrate beneath a photon sensing area of said multiple photosensor pixel image sensor.

59. The method for fabricating said pixel image sensor integrated circuit of claim 46 wherein forming said multiple photosensor pixel image sensor further comprises the steps of:
forming at least one readout circuit connected to receive and convert photoelectrons retained by said combined photosensing and charge storage device for conversion to an electronic signal indicative of a magnitude of said color component of said light received by one selected photo-sensing device of said plurality of photo-sensing devices.

60. The method for fabricating said pixel image sensor integrated circuit of claim 59 wherein forming said readout circuit further comprises the steps of:
forming a source follower connected to said storage node to receive and buffer a voltage indicative of a number of photoelectrons retained by said combined photosensing and charge storage device; and
forming a pixel select switch selectively connected to said source follower to transfer said buffered voltage indicative of the number of photoelectrons by said combined photosensing and charge storage device to external circuitry for further processing.

61. A combined photosensing and charge storage device incorporated within a color multiple sensor pixel image sensor fabricated on a surface of a substrate for sensing a principal color of differentiated color components of light impinging upon said multiple photosensor pixel image sensor and connected to sequentially receive photoelectrons from each of a plurality of photo-sensing devices incorporated within said color multiple sensor pixel image sensor.

62. The combined photosensing and charge storage device of claim 61 wherein each of said plurality of photo-sensing devices is structured for conversion of photons of one of said differentiated color components to photoelectrons.

63. The combined photosensing and charge storage device of claim 61 wherein a plurality of triggering switches are incorporated within said color multiple sensor pixel image sensor such that each triggering switch is connected to selectively and sequentially transfer photoelectrons from each of the plurality of photo-sensing devices to said combined photosensing and charge storage device.

64. The combined photosensing and charge storage device of claim 63 wherein at least one reset triggering switch is in communication with said combined photosensing and charge storage device and those of said triggering switches connected to said combined photosensing and charge storage device to place said plurality of photo-sensing devices said combined photosensing and charge storage device to a reset voltage level after integration and sensing of said photoelectrons.

65. The combined photosensing and charge storage device of claim 61 wherein said differentiated color components are selected from the group of color components consisting of red, green and blue.

66. The combined photosensing and charge storage device of claim 61 wherein said principal color is red.

67. The combined photosensing and charge storage device of claim 61 wherein said combined photosensing and charge storage device is sensed with a double sampling readout.

68. The combined photosensing and charge storage device of claim 61 wherein said plurality of photo-sensing devices are sensed with a correlated double sampling readout.

69. The combined photosensing and charge storage device of claim 63 wherein at least one of plurality of triggering switches of said color multiple sensor pixel image sensor are connected between two of said plurality of photo-sensing devices such that one of said two of said plurality of photo-sensing devices is an intermediary repository of said charge prior to transfer to said combined photosensing and charge storage device.

70. The combined photosensing and charge storage device of claim 69 wherein said two of said plurality of photo-sensing devices are connected together to provide binning of said charge from said two of the plurality of photo-sensing devices.

71. The combined photosensing and charge storage device of claim 61 wherein each of said plurality of photo-sensing devices of said color multiple sensor pixel image sensor are pinned photodiodes.

72. The combined photosensing and charge storage device of claim 71 wherein said pinned photodiodes comprise a diffusion of the first conductivity type and a shallow pinning diffusion of the second conductivity type within said diffusion of the first conductivity type and connected to a ground reference level.

73. The combined photosensing and charge storage device of claim 72 wherein each of said plurality of photo-sensing devices further comprises a deep diffusion of said second conductivity type connected to a substrate reference voltage source to deflect stray photoelectrons generated in said substrate beneath a photon sensing area of said multiple photosensor pixel image sensor.

74. The combined photosensing and charge storage device of claim 61 comprises a diffusion of said first conductivity type with a sufficient depth to collect photoelectrons converted from photons of said primary color.

75. The combined photosensing and charge storage device of claim 74 wherein said combined photosensing and charge storage device is formed in a deep diffusion of said first conductivity type connected to a power supply voltage source to collect stray photoelectrons generated in said substrate beneath a photon sensing area of said multiple photosensor pixel image sensor.

76. The combined photosensing and charge storage device of claim 61 wherein said color multiple sensor pixel image sensor further comprises at least one readout circuit connected to receive and convert photoelectrons retained by said combined photosensing and charge storage device for conversion to an electronic signal indicative of a magnitude of said color component of said light received by one selected photo-sensing device of said plurality of photo-sensing devices.

77. The combined photosensing and charge storage device of claim 76 wherein said readout circuit comprises:
a source follower connected to said storage node to receive and buffer a voltage indicative of a number of photoelectrons retained by said combined photosensing and charge storage device; and
a pixel select switch selectively connected to said source follower to transfer said buffered voltage indicative of the number of photoelectrons by said combined photosensing and charge storage device to external circuitry for further processing.
